(19) United States
(12) Patent Application Publication
(10) Pub. No.: US 2023/0197579 A1
(43) Pub. Date: Jun. 22, 2023

(54) NONLINEAR STRUCTURE FOR CONNECTING MULTIPLE DIE ATTACH PADS

(71) Applicant: TEXAS INSTRUMENTS INCORPORATED, Dallas, TX (US)

(72) Inventors: Xingfang Ma, Chengdu (CN); Juan Herbsommer, Allen, TX (US); Tiange Xie, Chengdu (CN); Alex Chin Sern Ting, Johor (MY)

(21) Appl. No.: 17/750,270

(22) Filed: May 20, 2022

Related U.S. Application Data
(63) Continuation of application No. PCT/CN2021/140014, filed on Dec. 21, 2021.

(30) Foreign Application Priority Data
Dec. 21, 2021 (WO) PCT/CN2021/140014

(51) Int. Cl. H01L 23/495; H01L 23/31

(52) U.S. Cl. CPC H01L 23/49548; H01L 23/3107; H01L 23/49503

(57) ABSTRACT

An integrated circuit package includes a first die attach pad (DAP) having a first bottom surface, a first semiconductor die attached to the first DAP, a second DAP having a second bottom surface, wherein the first bottom surface and the second bottom surface are coplanar, and a second semiconductor die attached to the second DAP. A nonlinear DAP linking structure couples the first DAP to the second DAP, wherein the DAP linking structure does not include any direct linear connections between the first DAP and the second DAP. The nonlinear DAP linking structure is configured to deform without causing the first DAP and the second DAP to become non-coplanar. A mold compound covers the first and second DAPs, the first and second semiconductor dies, and the nonlinear DAP linking structure.

### BACKGROUND

Lead frame strips are used in manufacturing packaged integrated circuits. Lead frame strips are comprised of multiple individual lead frame sections that are connected together by saw streets. An embedded lead frame strip is a lead frame strip to which integrated circuit dies are attached and then embedded in molding compound. Lead frame strips may include a semiconductor die attachment pad for attaching an integrated circuit die. The lead frame sections can be mechanically connected for stability during processing but are then separated prior to completion of the packaging process. Terminals on the integrated circuit dies may be electrically connected to lead frame leads and/or to other integrated circuit dies prior to completion of the packaged integrated circuit. In some packaged integrated circuits, bond wires are used to couple the terminals on the integrated circuit dies to leads on the lead frames and to other integrated circuit dies.

### SUMMARY

A lead frame for an integrated circuit module includes a first die attach pad (DAP) having a first bottom surface and a second DAP having a second bottom surface. The first bottom surface and the second bottom surface of the DAPs are coplanar. The lead frame further includes a nonlinear DAP linking structure coupling the first DAP to the second DAP. The lead frame does not include any direct linear connections between the first DAP and the second DAP. The nonlinear DAP linking structure includes two or more interconnected segments, wherein the segments are attached to each other at an angle such as in a zigzag shape.

An integrated circuit package includes a lead frame assembly with a first die attach pad (DAP) having a first bottom surface, a second DAP having a second bottom surface, and a nonlinear DAP tie bar structure coupling the first DAP to the second DAP. The first bottom surface and the second bottom surface of the DAPs are coplanar. The lead frame does not include any direct linear connections between the first DAP and the second DAP. The integrated circuit package further includes a first die mounted on the first DAP, a second die mounted on the second DAP, and a layer of mold compound covering the lead frame and the first and second dies. At least one bond wire has a first end electrically connected to the first die and a second end electrically connected to the second die. The nonlinear DAP tie bar structure has two or more interconnected segments, wherein the segments are attached to each other at an angle such as in a zigzag shape.

### BRIEF DESCRIPTION OF THE DRAWINGS

Having thus described the invention in general terms, reference will now be made to the accompanying drawings, wherein:

FIG. 1 is a top isometric view of an example lead frame.

FIGS. 2A and 2B illustrate mold flash leaking under a die attach pad for an example lead frame configuration.

FIGS. 3A and 3B illustrate mold flash leaking under a die attach pad in another example lead frame configuration.

FIG. 4 depicts an example lead frame strip having tie bar configurations that are configured to minimize movement of die attach pads out of plane as a result of thermal expansion, lead frame warpage, and/or internal stress.

FIGS. 5A and 5B illustrate the components of an example tie bar configuration and the resulting deformation of the structure when stress is applied.

FIG. 6 illustrates an example tie bar configuration for linking several lead strip sections as shown in FIG. 4.

FIG. 7 illustrates a tie bar configuration comprising a plurality of curved tie bar segments that are connected to individual die attach pads.

FIG. 8 is an isometric view of a packaged semiconductor device according to an example embodiment.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to ...” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

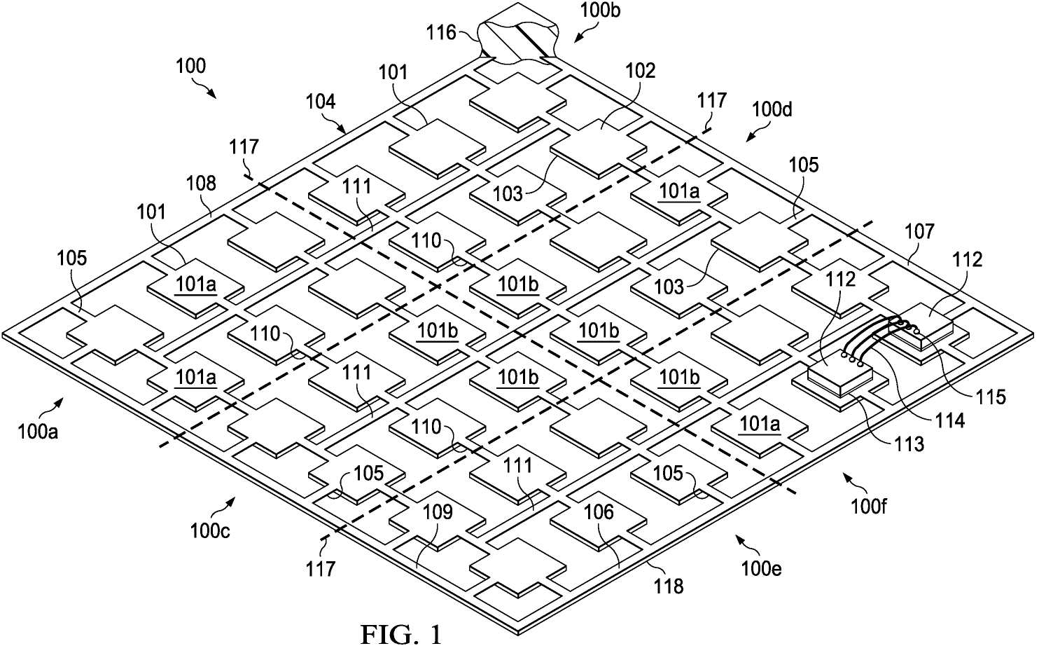

FIG. 1 illustrates a lead frame strip 100 having a plurality of interconnected die attach pad (DAP) portions 101. Each DAP portion 101 has a top surface 102 and a bottom surface 103. Peripheral ones 101a of the DAP portions 101 are connected to a frame 104 by peripheral tie bars 105. Frame 104 may be formed by a plurality of elongate frame members 106, 107, 108, 109. Interior ones 101b of the DAP portions 101 are connected to surrounding interior DAP portions 101b by interior tie bars 110. The interior tie bars 110 are connected to each other by cross tie bars 111. During the manufacturing process, integrated circuit dies 112 are mounted to the top surface 102 of DAP portions 101 using a die attach material 113. Bond wires 114 electrically connect terminals 115 of the integrated circuit dies 112 to terminals on other integrated circuit dies 112 or to lead frame leads (not shown).

As used herein, the term “tie bar” refers to a portion of a lead frame that is directly connected to, and mechanically supports, the die attach pad during packaging. The tie bars may connect the die attach pads to each other, to leads, or to a peripheral lead frame member or side rail, for example. The tie bars may have a uniform or non-uniform width.

Portions of the integrated circuit dies 112, the bond wires 114, and the lead frame strip 100 are encapsulated in a mold compound or encapsulant material 116. To simplify FIG. 1 only a portion of mold compound 116 is shown. Groups of the DAP portions 101 and integrated circuit dies 112 are spaced from one another by saw streets 117. Saw streets 117 are defined areas of the lead frame strip 100 and the molding compound 116 where groups of integrated circuit devices 112 can be separated in a later process step by cutting through the saw street to form sections. Upon the hardening of the mold compound 116, lead frame sections 100a-f within the lead frame strip 100 are cut apart or singulated for producing individual packages. Such singulation is typically accomplished via a sawing process. In a conventional mechanical saw process, a saw blade (or dicing blade) is typically advanced along saw streets 117 which extend in prescribed patterns between the lead frame sections 100a-f to separate the lead frame sections from one another. Example lead frame strip 100 illustrates a relatively evenly spaced 6 × 6 matrix of interconnected DAP portions 101 to simplify the description; however, it will be understood that the embodiments disclosed herein may be applied to a lead frame strip layout having any number of DAP portions having similar or dissimilar size.

Lead frame strip 100 may be fabricated from a copper sheet that is etched or stamped to form a pattern of DAP portions, thermal pads, and contacts. Lead frame strip 100 may be plated with tin or another metal that will prevent oxidation of the copper and provide a lower contact surface that is easy to solder. The backside of lead frame strip, such as the bottom surface 103 of DAP portions 101, includes a solderable metal layer 118 on a base metal. Lead frame strip 108 can be provided to a packaging process including a pre-plated material that includes the solderable metal layer. Alternatively, the solderable metal layer 118 can be applied to the base metal of lead frame strip 100 at a prior step in the packaging process. The solderable metal layer on the backside surface of the lead frame 100 and the DAP portions 101 form external terminals that are used to electrically connect to the integrated circuit dies 112.

During the manufacturing process some die attachment pads may be moved out of alignment so that they are not coplanar with the other die attachment pads. Problems can arise in existing art lead frames having multiple DAPs when there are non-coplanarities problem between DAP portions 101. Such non-coplanarities may occur, for example, due to lead frame thermal expansion, lead frame warpage, or internal stress during the mold process under high temperature. The non-coplanarities can lead to mold flash wherein mold compound 116 flows under DAP portions 101 and across bottom surface 103 thereby covering solderable metal layer 118, which prevents electrical connections to the integrated circuit dies 112. The tie bar configurations used in existing lead frame designs do not allow for release of internal stress, which results in warpage and non-coplanarities across the DAP portions.

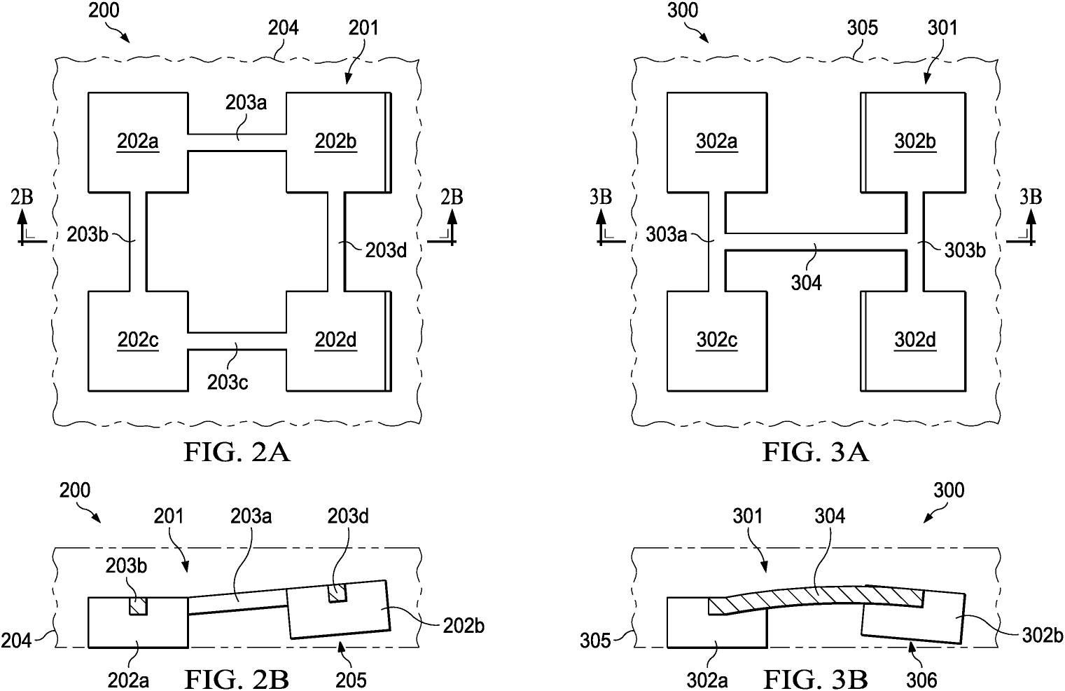

FIGS. 2A and 2B illustrate the problems caused by mold flash according to an example lead frame configuration. FIG. 2A shows a top view of a lead frame 201 comprising a plurality of DAP portions 202a-d. Individual tie bars 203a-d connect pairs of DAP portions 202a-d. After semiconductor dies (not shown) are mounted on DAP portions 202a-d, and the wire bonding process is performed, a mold compound 204 is used to encapsulate the components to create a package 200. During the mold process, thermal expansion, lead frame warpage, and/or internal stress may force some of the DAP portions 202 out of plane with the other DAP portions 202. FIG. 2B is a cross section view of the device shown in FIG. 2A showing DAP portion 202b being lifted out of plane due to stresses applied along tie bar 203a. As a result, during the molding process, mold compound 204 leaks under DAP portion 202b creating mold flash area 205, which prevents DAP 202b from being exposed outside of the package 200.

FIGS. 3A and 3B illustrate the problems caused by mold flash according to another example lead frame configuration. FIG. 3A shows a top view of a lead frame 301 comprising a plurality of DAP portions 302a-d. Individual tie bars 303a,b connect pairs of DAP portions 302a-d, and cross tie bar 304 links tie bars 303a,b. After semiconductor dies (not shown) are mounted on DAP portions 302a-d, mold compound 305 is used to encapsulate the components to create a package 300. During the molding process, thermal expansion, lead frame warpage, and/or internal stress may force some of the DAP portions 302 out of plane with the other DAP portions 302. FIG. 3B is a cross section view of the device shown in FIG. 3A showing DAP portion 302b being rotated out of plane due to warpage along cross tie bar 304. As a result, during the molding process, mold compound 305 leaks under DAP portion 302b creating mold flash area 306, which prevents DAP 302b from being exposed outside of the package 300.

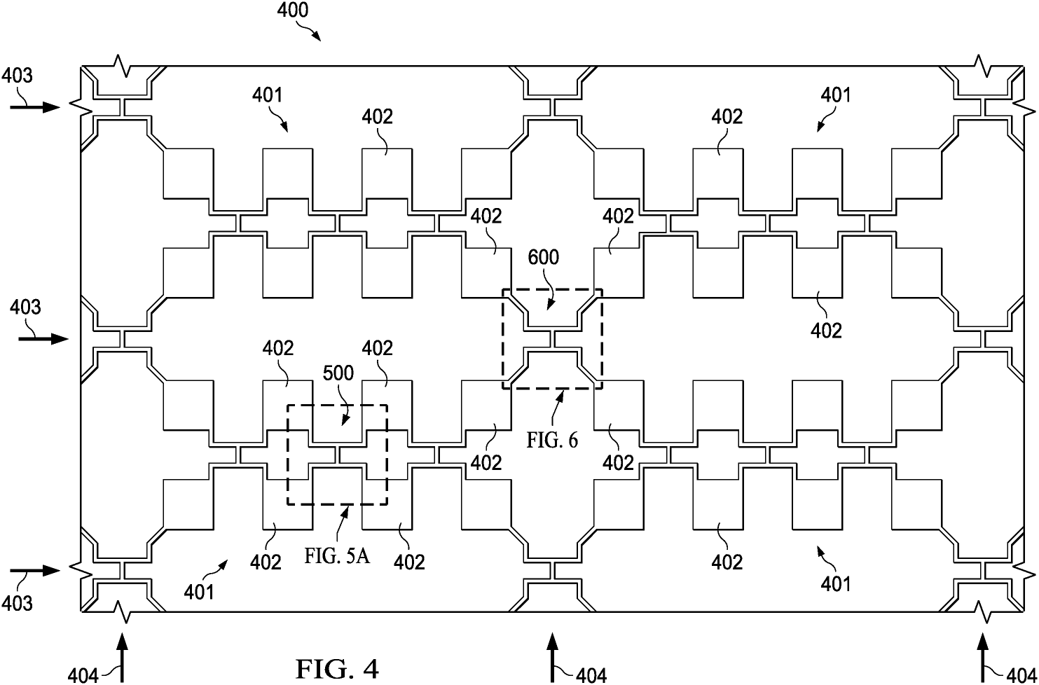

FIG. 4 depicts a portion of an example lead frame strip 400 having tie bar configurations that are configured to minimize movement of DAPs out of plane as a result of thermal expansion, lead frame warpage, and/or internal stress during the molding process. Lead frame strip 400 comprises a plurality of lead frame sections 401 wherein each section 401 comprises multiple DAPs 402. In the illustrated embodiment, each lead frame section 401 includes eight DAPs 402 that are laid out in a generally symmetrical manner. It will be understood that, in other configurations, the lead frame sections 401 may be the same or different and/or the DAPs 402 may be symmetrical or asymmetrical. As described above in reference to FIG. 1, during a manufacturing process, integrated circuit dies (not shown) may be mounted on DAPs 402, the integrated circuit dies may be connected to each other and to leads on the lead frame using wire bonding, and then the components may be encapsulated in a molding compound. The individual lead frame sections 401 with the encapsulated integrated circuit dies attached may be cut apart or singulated to produce individual packages. For example, lead frame sheet 400 may be cut along saw streets indicated generally along the direction of arrows 403 and 404.

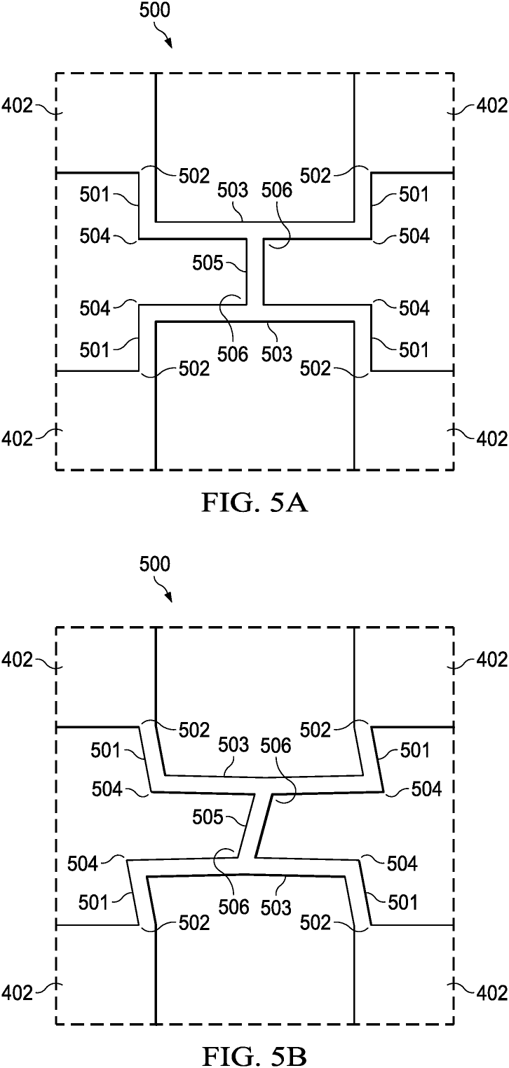

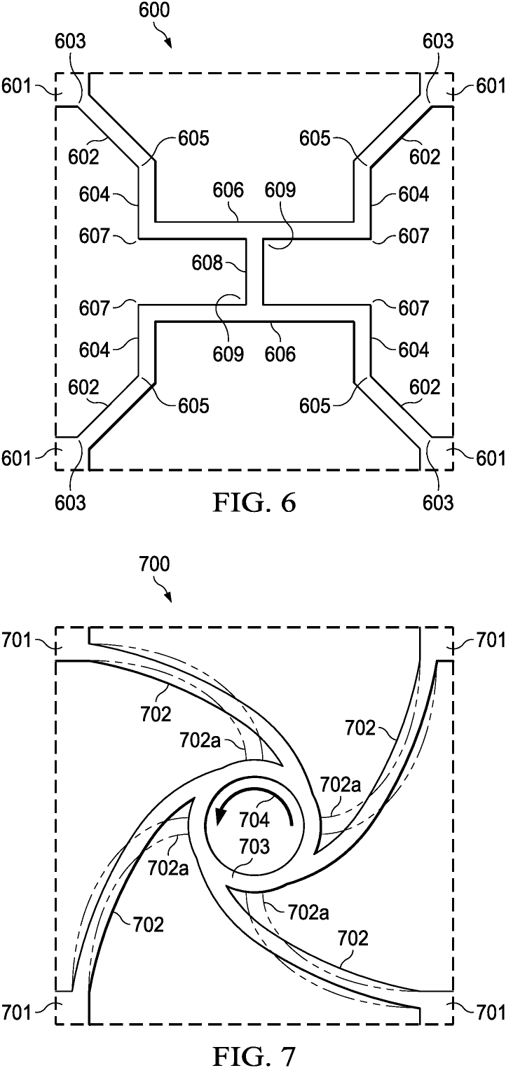

The DAPs 402 within each lead frame section 401 are coupled to each other via a tie bar configuration 500, which is shown in greater detail in FIG. 5A. The separate lead frame sections 401 are coupled to each other via a tie bar configuration 600, which is shown in greater detail in FIG. 6. Tie bar configurations 500 and 600 have multiple segments with a zigzag, skewed, or other nonlinear pattern. The segments of tie bar configurations 500 and 600 may be half-etched from the material used to create the lead frame strip 400. The structure of configurations 500 and 600 are flexible and will absorb stresses applied to the lead frame strip 400. This offsets the stresses on the DAPs 402 and prevents the DAPs 402 from rotating, twisting, or otherwise moving out of plane relative to lead frame strip 400. When an internal stress or external force is applied to the lead frame strip 400, the half-etched connection structures 500 and 600 will offset any deformations and will eliminate mold flash under DAPs 402.

FIG. 5A illustrates the components of an example tie bar configuration 500 that connects several DAPs 402. A tie bar segment 501 is coupled to each DAP 402 at a joint 502. Tie bar segments 501 are coupled to DAPs 402 generally at a corner region of the DAP 402 in the illustrated embodiment; however, in other embodiments, the tie bar segments 501 may be coupled to any edge of the DAPs 402. The tie bar segment 501 are also coupled to a cross tie bar 503 at a joint 504. Each cross tie bar 503 is indirectly coupled to a pair of DAPs 402 through tie bar segments 501. The cross tie bars 503 are coupled to a linking tie bar 505 at joints 506. The DAPs 402 are not directly linked to each other by individual tie bars, which allows tie bar configuration 500 to absorb stresses in the lead frame strip and to deform in response to forces applied to the lead frame strip without causing DAPs to move out of the plane of the lead frame.

FIG. 5B illustrates the movement of the components of tie bar configuration 500 when stress or forces are applied to a lead frame strip in an example embodiment, such as stress caused by high temperature during the mold process. Forces applied to the lead frame strip cause tie bar segments 501 to flex at joints 502 without pulling DAPs 402 out of plane with the other DAPs 402 on the lead frame strip. Movement of tie bar segments 501 result in corresponding movement of cross tie bars 503 and linking tie bar 505, which flex at joints 504 and 506. The tie bar components 501, 503, 505 may be half etched from the lead frame strip material, which makes those components more flexible and more susceptible to movement than the DAPs 402. Tie bar components 501, 503, 505 may flex or deform, for example, in a manner that keeps the components in a plane with DAPs 402 or above the plane of DAPs 402.

FIG. 6 illustrates the components of an example tie bar configuration 600. In one embodiment, DAPs 601 may represent corners of several lead strip sections as shown in FIG. 4. In other embodiments, tie bar configuration 600 may be used to connect DAPs within a lead frame section such as by replacing configuration 500. DAPs 601 are coupled to first tie bar segments 602 at joints 603. The first tie bar segments 602 are also coupled to second tie bar segments 604 at joints 605. The second tie bar segments 604 are coupled to a cross tie bar 606 at a joint 607. Cross tie bars 607 are coupled to each other by linking tie bar 608 at joints 609. Because DAPs 601 are not directly linked to each other by individual tie bars, the segments of tie bar configuration 600 can absorb stresses in the lead frame strip and will deform in response to forces applied to the lead frame strip. The tie bar segments 602, 604, 606, 608 are half etched from the lead frame strip material, which makes those components more flexible and more susceptible to movement than the DAPs 601. The tie bar segments 602, 604, 606, 608 can flex at joints 603, 605, 507. 609 to relieve stress in the lead frame.

In typical lead frames, such as lead frames 201 and 301 (FIGS. 2A, 3A), the DAP portions are linked by a single tie bar, such as 203 or 303. These lead frames do not have a way to absorb stress during the packaging process. The stresses cause the lead frame to deform thereby forcing the DAPs out of plane. In the examples shown in FIGS. 5A, 5B and 6, the tie bar configurations are adapted to absorb those stresses and to deform without forcing the DAPs out of plane. The single, straight tie bar connections result in stresses being transferred directly from one DAP to another. In the examples shown herein, the DAP linking structures do not include any direct linear connections between the DAP portions. Instead, the nonlinear DAP linking structure is configured to deform without causing one DAP portion to become non-coplanar relative to other DAP portions. The example DAP linking structures comprise at least three tie bar links between each DAP portion (e.g., links 501, 503, 501 (FIG. 5A) or links 602, 604, 606, 604, 602 (FIG. 6)). The example DAP linking structures also have at least two joints that allow the DAP linking structures to flex and deform when stress is applied to the lead frame (e.g., joints 504, 506 or joints 605, 607, 609). The ability to absorb stresses and forces within the DAP linking structures by flexing and deforming the DAP linking structures, which is not possible in the existing straight tie bar systems, allows the DAP portions to remain coplanar.

In other embodiments, the tie bar configuration used to link DAPs are not limited to linear segments but may include curved segments that may flex and absorb internal stresses in the lead frame strip by bending or unbending. For example, in FIG. 7, tie bar configuration 700 comprises a plurality of curved tie bar segments 702 that are connected to individual DAPs 701. The curved tie bar segments 702 are connected to a central hub 703. Forces in the lead frame sheet may cause the tie bar configuration 700 to move, such as rotating in the direction shown by arrow 704. This allows the curved tie bar segments 702 to flex by bending (or unbending if hub 703 rotated opposite the direction of arrow 704). The curved tie bar segments are shown in dashed lines 702a in the further bent position.

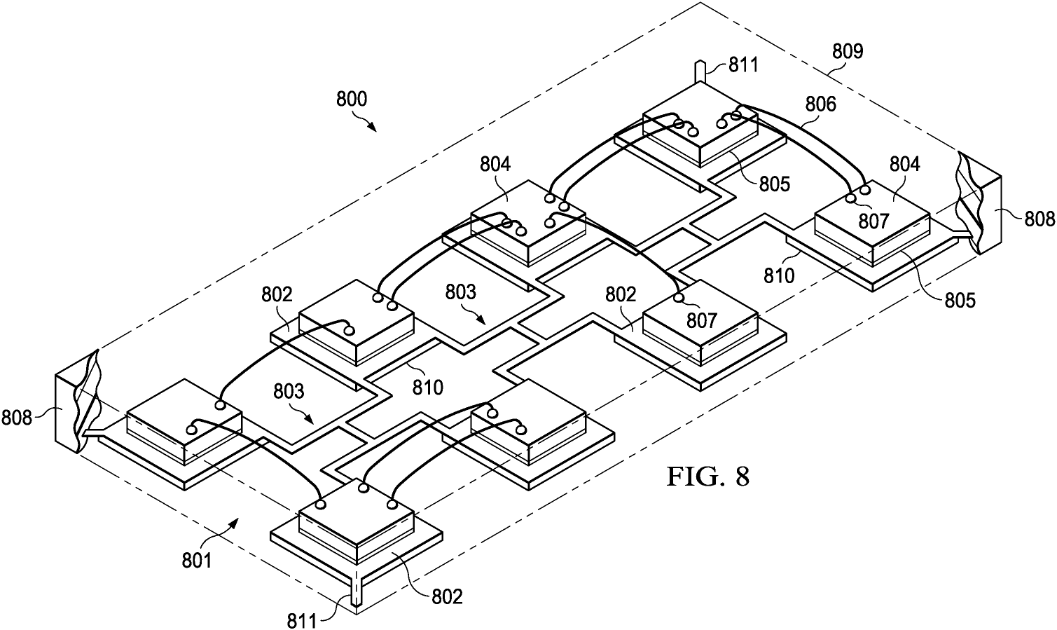

FIG. 8 illustrates a packaged semiconductor device 800 according to an example embodiment. The packaged semiconductor device 800 comprises a lead frame section 801 having a number of DAP portions 802. Nonlinear tie bar portions 803 of lead frame section 801 link the DAP portions 802. Nonlinear tie bar portions 803 may be implemented, for example, using the tie bar configuration 500 shown in FIGS. 5A and 5B or the tie bar configuration 600 shown in FIG. 6. Integrated circuit dies 804 are mounted to a top surface of DAP portions 802 using a die attach material 805. Bond wires 806 electrically connect terminals 807 of the integrated circuit dies 804 to terminals on other integrated circuit dies 804 and/or to lead frame leads (not shown) that allow for external connection to one or more integrated circuit dies 804. The lead frame strip section 801, DAP portions 802, nonlinear tie bar portions 803, integrated circuit dies 804, and bond wires 806 are encapsulated in a mold compound or encapsulant material 808. To simplify FIG. 8 only a portion of mold compound 808 is shown; however, it will be understood that mold compound 808 would fill the package dimensions shown by dashed line 809. Each DAP portion 802 has a bottom surface 810 that is exposed through a bottom surface of mold compound 808. The bottom surfaces 810 of DAP portions 802 are coplanar.

Lead frame section 801 may be a subsection of a larger lead frame strip, such as lead frame strip 400 show in FIG. 4. A singulation step during the manufacture of packaged semiconductor device 800 cuts the larger lead frame strip 400 into a number of separate lead frame sections 801. The separate lead frame sections 801 may have been coupled to each other by nonlinear tie bar portions, such as section the linking tie bar configuration 600 shown in FIG. 6. After singulation, only a portion 811 of the section linking tie bar configuration may be present in packaged semiconductor device 800.

Lead frame section 801 may be fabricated from a copper sheet that is etched or stamped to form a pattern of DAP portions 802 and nonlinear tie bar portions 803. The nonlinear tie bar portions 803 may be half-etched so that they are thinner relative to DAP portions 802. The nonlinear tie bar portions 803 comprise a plurality of segments that are coupled to each other at angles, such as at angles between 10-170 degrees, so that there is not a straight or linear path between two DAP portions 802. Instead, the path between the DAP portions 802 comprise one or more corners at variable angles such that the path has a zigzag, sawtooth, skewed, or other nonlinear pattern. Forces applied to lead frame strip section 801 during manufacture of packaged semiconductor device 800 are absorbed by nonlinear tie bar portions 803, such as by the deformation or bending of segments of nonlinear tie bar portions 803, so that the bottom surfaces 810 of DAP portions 802 remain coplanar.

In one example, a lead frame for an integrated circuit module comprises a first DAP having a first bottom surface, a second DAP having a second bottom surface, wherein the first bottom surface and the second bottom surface are coplanar, and a nonlinear DAP linking structure coupling the first DAP to the second DAP, wherein the lead frame does not include any direct linear connections between the first DAP and the second DAP.

The nonlinear DAP linking structure may comprise two or more interconnected segments that are attached to each other at an angle.

The nonlinear DAP linking structure may comprise a zigzag shape.

The first DAP, the second DAP, and the nonlinear DAP linking structure may be constructed from a single sheet of material, and the nonlinear DAP linking structure may be half-etched.

The nonlinear DAP linking structure may be adapted to deform without moving the first DAP or the second DAP out of a coplanar configuration when stress is applied to the nonlinear DAP linking structure.

The nonlinear DAP linking structure may comprise a first segment coupled to the first DAP, a second segment coupled to the second DAP, and a third segment coupled to the first segment at a first angle and coupled to the second segment at a second angle.

The lead frame may further comprise a third DAP having a third bottom surface, a fourth DAP having a fourth bottom surface, wherein the first, second, third, and fourth bottom surfaces are coplanar. The nonlinear DAP linking structure may be coupled to the third DAP and the fourth DAP. The nonlinear DAP linking structure may comprise a fourth segment coupled to the third DAP, a fifth segment coupled to the fourth DAP, a sixth segment coupled to the fourth segment at a third angle and coupled to the fifth segment at a fourth angle. A seventh segment may be coupled to the third segment and the sixth segment.

In another example, an integrated circuit package comprises a lead frame assembly having a first die attach pad (DAP) having a first bottom surface, a second DAP having a second bottom surface, wherein the first bottom surface and the second bottom surface are coplanar, and a nonlinear DAP tie bar structure coupling the first DAP to the second DAP, wherein the lead frame does not include any direct linear connections between the first DAP and the second DAP. A first die is mounted on the first DAP, a second die is mounted on the second DAP, and a layer of mold compound covers the lead frame and the first and second dies.

The integrated circuit package may further comprise at least one bond wire having a first end electrically connected to the first die and a second end electrically connected to the second die. The integrated circuit package may further comprise at least one bond wire having a first end electrically connected to the first die and a second end electrically connected to a lead configured to provide an external connection the first die.

The nonlinear DAP tie bar structure may comprise two or more interconnected segments, wherein the segments are attached to each other at an angle.

The nonlinear DAP tie bar structure may comprise a zigzag shape.

The first DAP, the second DAP, and the nonlinear DAP tie bar structure may be constructed from a single sheet of material, wherein at least a portion of the nonlinear DAP tie bar structure is half-etched.

The nonlinear DAP tie bar structure may be adapted to deform without moving the first DAP or the second DAP out of a coplanar configuration when stress is applied to the lead frame assembly.

The nonlinear DAP tie bar structure may comprise a first segment coupled to the first DAP, a second segment coupled to the second DAP, and a third segment coupled to the first segment at a first angle and coupled to the second segment at a second angle.

The integrated circuit package may further comprise a third DAP having a third bottom surface, a fourth DAP having a fourth bottom surface, wherein the first, second, third, and fourth bottom surfaces are coplanar, and wherein the nonlinear DAP tie bar structure is coupled to the third DAP and the fourth DAP. The nonlinear DAP tie bar structure may comprise a fourth segment coupled to the third DAP, a fifth segment coupled to the fourth DAP, a sixth segment coupled to the fourth segment at a third angle and coupled to the fifth segment at a fourth angle. A seventh segment may be coupled to the third segment and the sixth segment.

Another example integrated circuit package includes a first die attach pad (DAP) having a first bottom surface, a first semiconductor die attached to the first DAP, a second DAP having a second bottom surface, wherein the first bottom surface and the second bottom surface are coplanar, a second semiconductor die attached to the second DAP, and a nonlinear DAP linking structure coupling the first DAP to the second DAP. The DAP linking structure does not include any direct linear connections between the first DAP and the second DAP. The nonlinear DAP linking structure is configured to deform without causing the first DAP and the second DAP to become non-coplanar. A mold compound covers the first and second DAPs, the first and second semiconductor dies, and the nonlinear DAP linking structure in the example integrated circuit package.

A further example integrated circuit package includes a first die attach pad (DAP) having a first bottom surface, a second DAP having a second bottom surface, wherein the first bottom surface and the second bottom surface are coplanar, a nonlinear DAP tie bar structure coupling the first DAP to the second DAP, wherein the nonlinear DAP tie bar structure comprises at least three tie bar links between the first DAP and the second DAP, the at least three tie bar links configured to deform without causing the first DAP and the second DAP to become non-coplanar, a first die mounted on the first DAP, a second die mounted on the second DAP, and a mold compound covering the nonlinear DAP tie bar structure and the first and second dies.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. An integrated circuit package, comprising:
a first die attach pad (DAP) having a first bottom surface;
a first semiconductor die attached to the first DAP;
a second DAP having a second bottom surface, wherein the first bottom surface and the second bottom surface are coplanar;
a second semiconductor die attached to the second DAP;
a nonlinear DAP linking structure coupling the first DAP to the second DAP, wherein the DAP linking structure does not include any direct linear connections between the first DAP and the second DAP, and the nonlinear DAP linking structure configured to deform without causing the first DAP and the second DAP to become non-coplanar; and
a mold compound covering the first and second DAPs, the first and second semiconductor dies, and the nonlinear DAP linking structure.

2. The integrated circuit package of claim 1, wherein the nonlinear DAP linking structure comprises two or more interconnected segments, and wherein the segments are attached to each other at an angle.

3. The integrated circuit package of claim 1, wherein the nonlinear DAP linking structure comprises a zigzag shape.

4. The integrated circuit package of claim 1, wherein the first DAP, the second DAP, and the nonlinear DAP linking structure are constructed from a single sheet of material, and wherein the nonlinear DAP linking structure is half-etched.

5. The integrated circuit package of claim 1, wherein the nonlinear DAP linking structure is adapted to deform without moving the first DAP or the second DAP out of a coplanar configuration when stress is applied to the nonlinear DAP linking structure.

6. The integrated circuit package of claim 1, wherein the nonlinear DAP linking structure comprises:
a first segment coupled to the first DAP;
a second segment coupled to the second DAP; and
a third segment coupled to the first segment at a first angle and coupled to the second segment at a second angle.

7. The integrated circuit package of claim 6, further comprising:
a third DAP having a third bottom surface;
a fourth DAP having a fourth bottom surface, wherein the first, second, third, and fourth bottom surfaces are coplanar; and
the nonlinear DAP linking structure is coupled to the third DAP and the fourth DAP.

8. The integrated circuit package of claim 7, wherein the nonlinear DAP linking structure comprises:
a fourth segment coupled to the third DAP;
a fifth segment coupled to the fourth DAP;
a sixth segment coupled to the fourth segment at a third angle and coupled to the fifth segment at a fourth angle.

9. The integrated circuit package of claim 8, wherein the nonlinear DAP linking structure comprises:
a seventh segment coupled to the third segment and the sixth segment.

10. An integrated circuit package, comprising:
a first die attach pad (DAP) having a first bottom surface;
a second DAP having a second bottom surface, wherein the first bottom surface and the second bottom surface are coplanar;
a nonlinear DAP tie bar structure coupling the first DAP to the second DAP, wherein the nonlinear DAP tie bar structure comprises at least three tie bar links between the first DAP and the second DAP, the at least three tie bar links configured to deform without causing the first DAP and the second DAP to become non-coplanar;
a first die mounted on the first DAP;
a second die mounted on the second DAP; and
a mold compound covering the nonlinear DAP tie bar structure and the first and second dies.

11. The integrated circuit package of claim 10, further comprising:
at least one bond wire having a first end electrically connected to the first die and a second end electrically connected to the second die.

12. The integrated circuit package of claim 10, further comprising:
at least one bond wire having a first end electrically connected to the first die and a second end electrically connected to a lead configured to provide an external connection the first die.

13. The integrated circuit package of claim 10, wherein the nonlinear DAP tie bar structure comprises two or more interconnected segments, and wherein the segments are attached to each other at an angle.

14. The integrated circuit package of claim 10, wherein the nonlinear DAP tie bar structure comprises a zigzag shape.

15. The integrated circuit package of claim 10, wherein the first DAP, the second DAP, and the nonlinear DAP tie bar structure are constructed from a single sheet of material, and wherein at least a portion of the nonlinear DAP tie bar structure is half-etched.

16. The integrated circuit package of claim 10, wherein the nonlinear DAP tie bar structure is adapted to deform without moving the first DAP or the second DAP out of a coplanar configuration when stress is applied to the nonlinear DAP tie bar structure.

17. The integrated circuit package of claim 10, wherein the nonlinear DAP tie bar structure comprises:
a first segment coupled to the first DAP;
a second segment coupled to the second DAP; and
a third segment coupled to the first segment at a first angle and coupled to the second segment at a second angle.

18. The integrated circuit package of claim 10, further comprising:
a third DAP having a third bottom surface;
a fourth DAP having a fourth bottom surface, wherein the first, second, third, and fourth bottom surfaces are coplanar; and
the nonlinear DAP tie bar structure is coupled to the third DAP and the fourth DAP.

19. The integrated circuit package of claim 18, wherein the nonlinear DAP tie bar structure comprises:
a fourth segment coupled to the third DAP;
a fifth segment coupled to the fourth DAP;
a sixth segment coupled to the fourth segment at a third angle and coupled to the fifth segment at a fourth angle.

20. The integrated circuit package of claim 19, wherein the nonlinear DAP tie bar structure comprises:
a seventh segment coupled to the third segment and the sixth segment.
